(19) United States
(12) Patent Application Publication
(10) Pub. No.: US 2002/0185641 A1
(43) Pub. Date: Dec. 12, 2002

(54) Compound semiconductor device

(76) Inventor: Mikio Mohri, Tokyo (JP)

Correspondence Address: Venable, P.O. Box 34385, Washington, DC, 20043-9998, US

(21) Appl. No.: 10/143,768

(22) Filed: May 14, 2002

(30) Foreign Application Priority Data
May 18, 2001 (JP) 149796/2001

(51) Int. Cl. H01L 29/06

(52) U.S. Cl. 257/11

(57) ABSTRACT

A compound semiconductor device comprising: an semi-insulated InP substrate; a plurality of interconnections formed on the semi-insulated InP substrate; and an insulating film formed between the interconnections, the insulating film being a silicon oxide.

Accordingly, the compound semiconductor device can avoid a surface-leakage.

### BACKGROUND OF THE INVENTION

1. Field of the Invention

The present invention generally relates to a compound semiconductor device, and more particularly, the present invention relates to the compound semiconductor device having an insulating film on a semi-insulated InP substrate.

This application is a counterpart of Japanese application Serial Number 149796/2001, filed May 18, 2001, the subject matter of which is incorporated herein by reference.

2. Description of the Related Art

In general, an HPT (heterojunction-bipolar-phototransistor), a PD (photodiode), and a HEMT (high-electron-mobility-transistor), which employ a semi-insulated InP substrate.

Here, the HPT or the PD serves as a photo-detector for an optical-communication O/E converter.

These devices provide an insulating film for isolating between interconnections. The insulating film is made up of a silicon nitride (SiNₓ, x>0). The silicon nitride is formed by a plasma CVD (chemical vapor deposition). Here, the plasma CVD uses a mixed gas of a SiH₄, an NH₃, and an N₂.

In a structure having the insulating film as the silicon nitride, a surface-leakage comes of an interface between the semi-insulated InP and the silicon nitride.

### SUMMARY OF THE INVENTION

An object of the present invention is to provide a compound semiconductor device that can avoid the surface-leakage.

According to one aspect of the present invention, for achieving the above object, there is provided a compound semiconductor device comprising a semi-insulated InP substrate, a plurality of interconnections formed on the semi-insulated InP substrate, and an insulating film formed between the interconnections, the insulating film being a silicon oxide.

### BRIEF DESCRIPTION OF THE DRAWINGS

While the specification concludes with claims particularly pointing out and distinctly claiming the subject matter that is regarded as the invention, the invention, along with the objects, features, and advantages thereof, will be better understood from the following description taken in connection with the accompanying drawings, in which:

FIG. 1 is a cross-sectional view showing a compound semiconductor device according to a preferred embodiment of a present invention.

FIG. 2 is a rough perspective diagram of the structure object before forming the surface protection film of a waveguide PIN photo-diode.

FIG. 3 is a cross-sectional view showing an I-V characteristic of a PIN photo-diode.

FIG. 4A-FIG. 4D are plane views showing a manufacturing process of a PIN photo-diode of FIG. 2.

FIG. 5A-FIG. 5D are sectional views cut along with the x-x line of FIG. 4.

### DETAILED DESCRIPTION OF THE PREFERRED EMBODIMENTS

A compound semiconductor device according to a preferred embodiment of a present invention will hereinafter be described in detail with reference to the accompanying drawings.

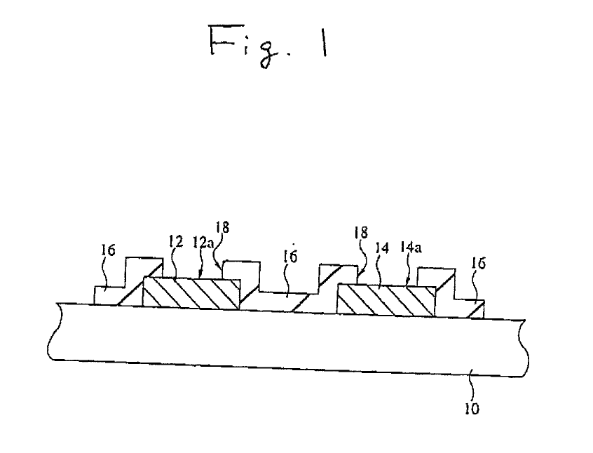

With reference to FIG. 1, it explains about the preferred embodiment of this invention. FIG. 1 is a cross-sectional view showing a compound semiconductor device according to a preferred embodiment of a present invention.

With the preferred embodiment, the structure object (this is made into the structure object A.) of this invention which uses as an insulating film a silicon oxide film which deposited by a plasma CVD. On the other hand, for comparing with the preferred embodiment, the structure object (it considers as the structure object B and the structure object C.) which uses as an insulating film a silicon nitride film which deposited by the plasma CVD method like the structure object A are prepared. Each structure object A-C is taken as the structure shown in FIG. 1.

As shown in FIG. 1, structure object A-C are made up of two electrodes 12 and 14 which estranged mutually and are formed on a semi-insulated InP substrate 10, and this semi-insulated InP substrate 10, and an insulating film 16 which has the window 18 which a part of upper surfaces 12a and 14a of each electrodes 12 and 14 expose, and was prepared on this semi-insulated InP substrate 10. Here, the semi-insulated InP substrate 10 is made up of an InP:Fe substrate.

Manufacture of these structure objects forms the laminating metal film which consists of Ti/Pt/Au by electronic beam vacuum evaporation on the semi-insulated InP substrate 10. This laminating metal film is used as electrodes. Here, the interval between two electrodes is set up so that width may be set to 10 .m, and a length may be set to 14 .m.

After carrying out the vacuum evaporation of the electrodes, it heat-treats at the temperature of 400 degrees C to the electrodes at least.

The current value when applying the voltage of 3V between the electrodes of each structure objects A-C is measured after heat treatment. The current value as a first measurement result is as in Table 1.

Next, the silicon oxide film as an insulating film is formed of Plasma CVD to the structure object A, using the mixed gas which consists of SiH₄/N₂O/N₂ as generation gas. Growth conditions set the flux ratio of mixed gas to SiH₄/N₂O/N₂=40/900/400 sccm, made substrate temperature Ts 300 degrees C, set pressure of mixed gas to 1.2×10² Pa, and set RF power to 20 W.

However, the SiH₄ gas of 40 sccm includes nitrogen and SiH₄ gas as a main ingredients. Concretely, the SiH₄ gas of 40 sccm consists a gas including SiH₄ gas of 20 volume %. On this condition, the silicon oxide film with a film thickness of 100 nm was formed.

On the other hand, the silicon nitride film as an insulating film is formed of a plasma CVD to the structure object B, using the mixed gas which consists of SiH₄/NH₃/N₂ as generation gas. Growth conditions set the flux ratio of mixed gas to SiH₄/NH₃/N₂=70/10/25 sccm, made substrate temperature Ts 300 degrees C, set pressure of mixed gas to 1.33×10² Pa, and set RF power to 70 W. However, the SiH₄ gas of 40 sccm includes nitrogen and SiH₄ gas as the main ingredients. Concretely, the SiH₄ gas of 40 sccm consists a gas including SiH₄ gas of 20 volume %. On this condition, the silicon nitride film with a film thickness of 100 nm was formed.

In the structure object A and the structure object B, after forming the insulating film, respectively, an etching process is performed on each insulating film. Consequently, a part of upper surface of two electrodes is exposed, and a window is formed. Thereby, the structure object A for an experiment as shown in FIG. 1, and the structure object B are acquired.

The structure object C makes substrate temperature Ts 200 degrees C, and other conditions form the silicon nitride film which turns into an insulating film on the same conditions as the structure object B.

The current value when applying the voltage of 3V between the electrodes of each structure objects A-C is measured after heat treatment. The current value as a second measurement result is as in Table 1.

Consequently, in the structure object A, in the first measurement, current values were 1.20 nA, and they were 2.99 nA in the second measurement. Therefore, it turns out with the structure object after forming the structure object and the silicon oxide film after the electrode formation that surface-leakage current hardly occurs.

TABLE 1

| | structure | structure | structure |
|---|---|---|---|
| | object A | object B | object C |
| first | 1.20 nA | 1.33 nA | 2.10 nA |
| measurement | | | |
| second | 2.99 nA | 284.8 nA | 8.99 nA |
| measurement | | | |

Moreover, in the structure object B, it was increasing to 284.8 nA by the second measurement to current values having been 1.33 nA in the first measurement. Therefore, by having formed the silicon nitride film showed that much surface-leakage current had occurred.

Moreover, in the structure object C, it was increasing even by about 4280 times with 8.99.A by the second measurement to current values having been 2.10 nA in the first measurement. Therefore, by forming a silicon nitride film like the structure object B, and being formed at a low substrate temperature showed that surface-leakage current increased further.

Moreover, structures other than insulating film 16 of the structure object A and the structure object B are the same, and only the generation gas of the insulating film 16 differs. Therefore, NH₃ gas contained in the generation gas for forming a SiN film as an insulating film of the structure object B is conjectured to be the cause of surface-leakage.

In a deposition process, P contained in the semi-insulated InP substrate is desorption-ionized by reacting with NH₃. As a result, the substrate surface has conducting properties since it will be in an In-rich state. Since two electrodes are formed in the surface of the substrate having conducting properties, leak current will flow, between the electrodes, through the surface of a substrate. Therefore, the insulating film can be formed by using as a silicon oxide film the insulating film formed on the substrate, without using NH₃ gas. Therefore, a phosphorous (P) in the substrate is not desorption-ionized and generating of surface-leakage current can be prevented.

Moreover, it may be apply a laminating structure object containing a silicon oxide film as an insulating film. However, the film of the side that contacts the substrate is the silicon oxide film.

Therefore, it is also possible to use as the laminating structure film of a silicon oxide film and a silicon nitride film for a surface protection film or an interlayer-insulating layer, formed on the substrate, for example.

Next, it explains about a preferred embodiment that applies this invention to a waveguide PIN photo-diode.

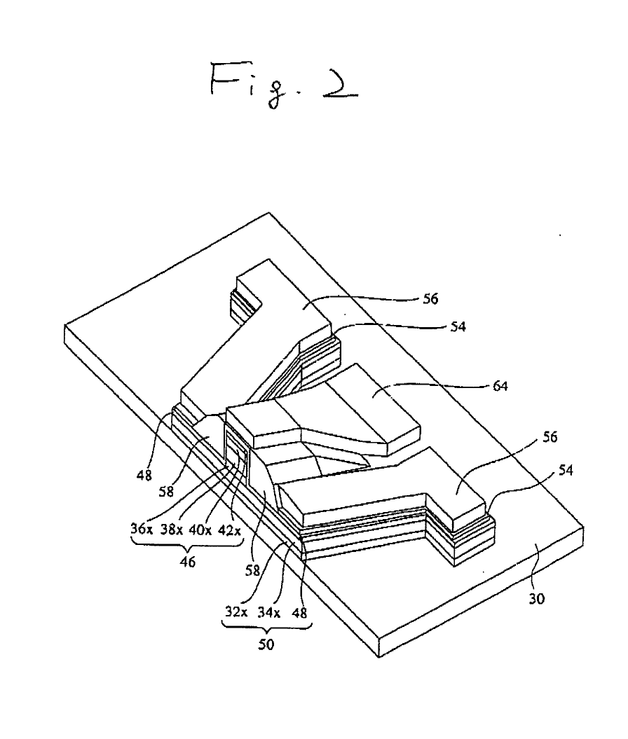

The composition of waveguide PIN photo-diode of this case of the operation is shown in FIG. 2. FIG. 2 is a rough perspective diagram of the structure object before forming a surface protection film of waveguide PIN photo-diode. This PIN photo-diode has, on (100) plane surface of a substrate 30, a MESA structure part 50 including an n⁺-semi-insulated InP layer as a first clad layer 32x, and an n⁺-InGaAsP layer 34x as a first core layer. A ridge structure 46 is made up of a.-InGaAs layer as photo acceptance layer 36x, a p⁺-InGaAsP layer as a second core layer 38x, a p⁺-semi-insulated InP layer as a second clad layer 40x, and a p⁺⁺-InGaAs layer as a contact layer 42x, which are sequentially formed on a top surface of the MESA structure part 50. A polyimide is formed, like a sidewall spacer, on a sidewall of the ridge structure 46 via a silicon-nitride film 48.

Moreover, an n type electrode of two-layer structure is formed on the MESA structure part 50 through the silicon nitride film 48.

The n-type electrode is made up of an n-type wiring electrode 56, and an n-type contact electrode 54 formed under the n type wiring electrode 56.

The n-type contact electrode 54 is formed so as to contact with a surface of the n⁺-InGaAsP layer 34x of the MESA structure part 50. An n-type contact electrode 54 consists of AuGe/nickel/Au. An n-type wiring electrode 56 consists of Ti/Pt/Au. A p-type electrode of two-layer structure is formed so as to extend from a part of upper surface of the ridge structure part 46 to the surface of the substrate. Here, the p-type wiring electrode 64 of the p-type electrode is shown by FIG. 2. In addition, the p-type contact electrode is formed, under the p-type wiring electrode 64, so as to contact with the surface of a p++-InGaAs layer 42x of the ridge structure part 46. A p-type contact electrode consists of Ti/Pt/Au (referred to as a first Ti/Pt/Au). A p-type wiring electrode 64 also consists of Ti/Pt/Au (referred to as a second Ti/Pt/Au).

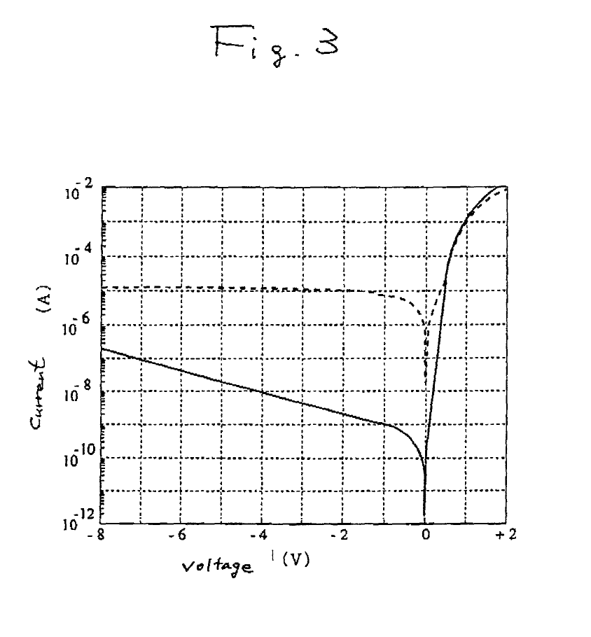

The above PIN photo-diodes are arbitrarily formed suitably using an epitaxial growth method, photo lithography technology, etching technology, the vacuum evaporation method, etc. The I-V characteristic of the PIN photo-diode obtained here is measured. By impressing the voltage from −8V to +2V between P type electrode and n type electrode, change of the current which flows among these electrode is measured. A measurement result is shown in FIG. 3. The curve shown as the solid line of FIG. 3 is the I-V characteristic of this PIN photo-diode.

As shown in FIG. 3, it turns out that the rectification characteristic as a photo-diode is acquired.

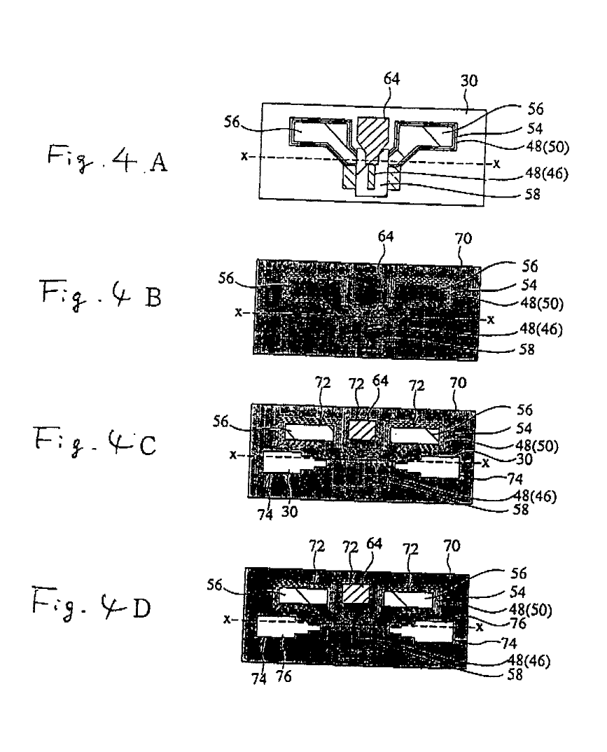

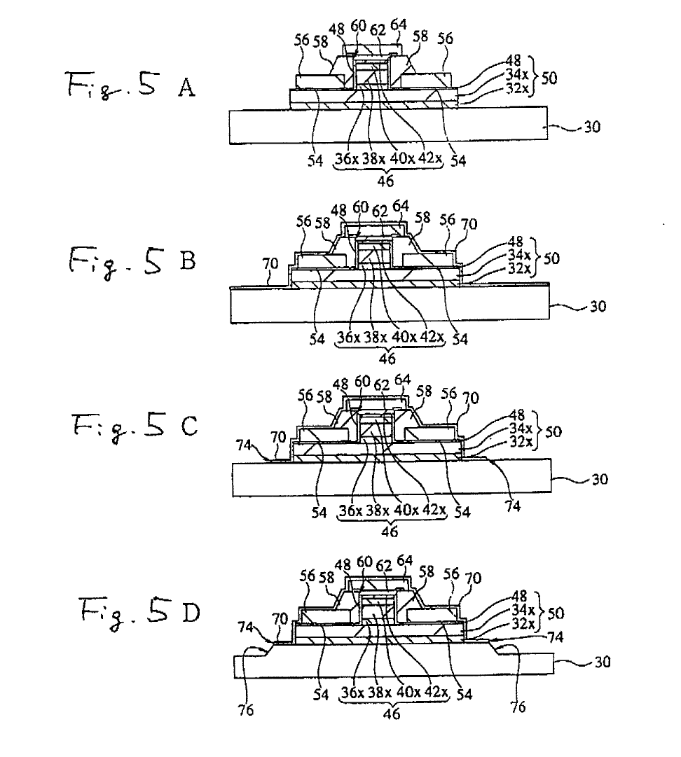

Next, with reference to FIGS. 4 and 5, the main manufacturing processes after manufacturing the PIN photo-diode of this invention are explained. FIG. 4 is a plane view showing the manufacturing process of the PIN photo-diode of FIG. 2. FIG. 5 is a sectional view cut along with the x-x line of FIG. 4. As shown by FIG. 4A and FIG. 5A, this is the plane view and sectional view of a PIN photo-diode having shown in FIG. 2. As shown by FIG. 4B and FIG. 5B, SiO2 film is formed all over the field (100) of the semi-insulated InP substrate 30 of a PIN photo-diode as a surface protection film 70. SiO2 film is formed so that a thickness may be set to 100 nm. Here, SiO2 film 70 is formed of Plasma CVD using the mixed gas which consists of SiH4/N2 O/N2 as generation gas. Deposition conditions set the flux ratio of generation gas to SiH4/N2O/N2=40/900/400 sccn, make substrate temperature Ts 300 degrees C, set pressure of mixed gas to 1.2×102 Pa, and set RF power to 20 W. As shown by FIG. 4C and FIG. 5C, RIE performs etching processing partially to SiO2 film 70, and the window 72 for wiring electrode and the window 74 for V slot formation are simultaneously formed in SiO2 film 70. The I-V characteristic of the PIN photo-diode formed of the above-mentioned process is measured. Measurement of this I-V characteristic is performed by measuring the current value when impressing voltage between p-wiring electrode 64 and n-wiring electrode 56 which are exposed from a window 72. Consequently, the same characteristic was acquired as the solid line of FIG. 3 showed. Therefore, it turns out that surface-leakage does not arise though SiO2 film 70 is formed on a substrate 30 as a surface protection film. In addition, the curve shown with the dashed line of FIG. 3 is an I-V characteristic curve when the surface protection film of a PIN photo-diode forms a SiNx film instead of SiO2 film 70. According to the curve shown with the dashed line of FIG. 3, when especially the voltage (0-8V) of an opposite direction is impressed, the current value is increasing sharply and the rectification characteristic as a diode is not acquired. Increase of this current value is based on generating of the leak current produced between p-wiring electrode 64 and n-wiring electrode 56. Therefore, in the PIN photo-diode equipped with the semi-insulated InP substrate so that clearly, if the curve shown with the dashed line was compared with the curve shown as the solid line, generating of surface-leakage current can be prevented by using SiO2 film as a surface protection film 70. Therefore, in this photo-diode, since the increase in opposite direction current can be controlled, effects, such as an increase in stabilization of the diode characteristic, high-speed operation of 40 GHz or more, and the minimum light-intercepting sensitivity and improvement in a S/N ratio, are expectable.

.It returns to explanation of a manufacturing process.

As shown by FIG. 4D and FIG. 5D, a V slot 76 for a cleavage is formed using wet etching to the substrate 30 exposed from a window 74. The V slot 76 has a depth of dozens of micrometers from the surface of a substrate 30. Here, HCl/H3PO4 mixed-solution is used as etchant.

After that, for using as a light-intercepting face an edge of the ridge structure part 46 in (001) plane of the substrate 30, after fixing a structure object on a flat stand, a wedge is perpendicularly pressed to the V slot 76. A substrate 30 is cleavage(d) as the V slot 76 is extended using this wedge. Thereby, the light-intercepting face is formed. Then, a waveguide PIN photo-diode is obtained by forming a reflective prevention film so that the light-intercepting face may be worn.

According to the compound semiconductor device of this invention, it is characterized by being arranged so that two or more electrodes (wiring) estranged and arranged on a semi-insulated InP compound semiconductor substrate and these electrodes may be covered, and consisting of SiO2 films as an insulating film so that clearly from the explanation mentioned above. This insulating film may consist of only SiO2 films. Moreover, as long as the insulating film which contacts with an semi-insulated InP substrate is SiO2 film, it may be formed by the laminating structure film of SiO2 film and other insulating films. As other insulating films, a silicon-nitride film is sufficient. Consequently, the PIN photo-diode which does not have surface-leakage on the semi-insulated InP substrate surface can be obtained. Therefore, degradation of the device characteristic by surface-leakage can be prevented.

While the present invention has been described with reference to the illustrative embodiments, this description is not intended to be construed in a limiting sense. Various modifications of the illustrative embodiments, as well as other embodiments of the invention, will be apparent to those skilled in the art on reference to this description. It is therefore contemplated that the appended claims will cover any such modifications or embodiments as fall within the true scope of the invention.

What is claimed is:

1. A compound semiconductor device comprising:
a semi-insulated InP substrate;
a plurality of interconnections formed on the semi-insulated InP substrate; and
an insulating film formed between the interconnections, the insulating film being a silicon oxide.

2. A compound semiconductor device as claimed in claim 1, wherein the insulating film serves as a surface protection film or an interlayer-insulating layer.

3. A compound semiconductor device as claimed in claim 1, wherein the silicon oxide film is formed of a plasma CVD using a mixed gas which consists of SiH4/N₂O/N₂ as generation gas,

4. A compound semiconductor device as claimed in claim 3, wherein a deposition conditions of the plasma CVD set SiH₄/N₂O/N₂=401900/400 sccn as a flux ratio of generation gas, 300 degrees C as a substrate temperature, 1.2×10² Pa as a mixed gas pressure, and 20 W as a RF power.

5. A compound semiconductor device as claimed in claim 1, wherein a waveguide PIN photodiode is formed on the semi-insulated InP substrate.

6. A compound semiconductor device comprising:
a semi-insulated InP substrate;
a plurality of interconnections formed on the semi-insulated InP substrate; and
a laminating structure object as an insulating film formed so as to cover the interconnections, the laminating structure object containing a silicon oxide film, a film of the side that contacts the substrate being the silicon oxide film.

7. A compound semiconductor device as claimed in claim 6, wherein the laminating structure film comprises the silicon oxide film and a silicon nitride.

8. A compound semiconductor device as claimed in claim 6, wherein the insulating film serves as a surface protection film or an interlayer-insulating layer.

9. A compound semiconductor device as claimed in claim 6, wherein the silicon oxide film is formed of a plasma CVD using a mixed gas which consists of SiH₄/N₂O/N₂ as generation gas,

10. A compound semiconductor device as claimed in claim 9, wherein a deposition conditions of the plasma CVD set SiH₄/N₂O/N₂=40/900/400 sccn as a flux ratio of generation gas, 300 degrees C as a substrate temperature, 1.2×10² Pa as a mixed gas pressure, and 20 W as a RF power.

11. A compound semiconductor device as claimed in claim 1, wherein a waveguide PIN photodiode is formed on the semi-insulated InP substrate.
